(19) United States
(12) Patent Application Publication
(10) Pub. No.: US 2025/0210361 A1
(43) Pub. Date: Jun. 26, 2025

(54) Electron-Stimulated Etching of Silicon

(71) Applicant: Applied Materials, Inc., Santa Clara, CA (US)

(72) Inventors: Sonam Dorje SHERPA, San Ramon, CA (US); Alok RANJAN, Sunnyvale, CA (US); Yang YANG, Cupertino, CA (US); Kartik RAMASWAMY, San Jose, CA (US)

(21) Appl. No.: 18/395,440

(22) Filed: Dec. 22, 2023

(51) Int. Cl. H01L 21/3065; H01L 21/67

(52) U.S. Cl. CPC H01L 21/3065; H01L 21/67069

(57) ABSTRACT

Methods and apparatus for processing a substrate which include contacting the substrate comprising silicon in a processing chamber with a fluorine etchant at a substrate temperature, pressure, and for a period of time sufficient to form a fluorine-containing reaction layer on a surface of the substrate and irradiating the fluorine-containing reaction layer on the surface of the substrate with electrons having an energy sufficient for electron-impact dissociation thereby releasing atomic fluorine to etch the surface of the substrate.

### FIELD

Embodiments of the present disclosure generally relate methods and apparatus for etching a substrate. More specifically, embodiments described herein relate to methods and apparatus for physisorption electron beam etching.

### BACKGROUND

In the semiconductor manufacturing industry, various technological advances have enabled production of increasingly complex devices at advanced technology nodes. For example, device feature sizes have been reduced to the nanometer scale and the geometric complexity of such features has grown increasingly complex. Etching processes used to fabricate such devices are often a limiting factor in further development of advanced devices.

Reactive ion etching (RIE) is a conventional etching technique which utilizes ion bombardment to induce etching reactions on a substrate. Generating anisotropic etching profiles is possible with RIE, however, certain ion energy thresholds are often necessary to induce desired etching reactions and to control the etching profile. The ion energy thresholds often reduce etch selectivity and may damage the structure being etched.

Electron beams are another technology commonly used in the semiconductor manufacturing industry. Electrons beams, when utilized in combination with chemisorption of suitable etching gas chemistries are capable of etching a substrate. However, the inventors have observed that conventional ion-driven silicon etching, which typically utilizes chlorine-based chemistries, requires a very tight control of ion energy to achieve selectivity, along with clogging of narrow structures on the order of less than 10 nm, which reduce accessibility of corners of high aspect ratio structures resulting in corner residues, and form tapered profiles. There is a need in the art for improvements in substrate processing.

### SUMMARY

Methods and apparatus for processing a substrate are provided herein. In embodiments, a method of processing a substrate comprises contacting the substrate comprising silicon in a processing chamber with a fluorine etchant at a substrate temperature, pressure, and for a period of time sufficient to form a fluorine-containing reaction layer on a surface of the substrate; and irradiating the layer of the fluorine-containing reaction layer on the surface of the substrate with electrons having an energy sufficient to cause electron-impact dissociation of the fluorine-containing reaction layer thereby releasing atomic fluorine to etch the surface of the substrate.

In embodiments, a method of etching a substrate comprises an etching cycle comprising contacting the substrate comprising silicon in a processing chamber with a fluorine etchant at a substrate temperature, pressure, and for a period of time sufficient to form a fluorine-containing reaction layer fluorine-containing reaction layer on a surface of the substrate; purging the processing chamber with an inert gas; irradiating the fluorine-containing reaction layer on the surface of the substrate with electrons having an energy sufficient for electron-impact dissociation of the fluorine-containing reaction layer thereby releasing atomic fluorine to etch the surface of the substrate; and purging the processing chamber with the inert gas, wherein the etching cycle is repeated a plurality of times.

In embodiments, a non-transitory, computer readable medium has instructions stored thereon that, when executed, cause a method of processing a substrate comprising a processing cycle, comprising contacting the substrate comprising silicon in a processing chamber with a fluorine etchant at a substrate temperature, pressure, and for a period of time sufficient to form a fluorine-containing reaction layer on a surface of the substrate; and irradiating the fluorine-containing reaction layer on the surface of the substrate with electrons having an energy sufficient for electron-impact dissociation of the fluorine-containing reaction layer thereby releasing atomic fluorine to etch the surface of the substrate.

Other and further embodiments of the present disclosure are described below.

### BRIEF DESCRIPTION OF THE DRAWINGS

Embodiments of the present disclosure, briefly summarized above and discussed in greater detail below, can be understood by reference to the illustrative embodiments of the disclosure depicted in the appended drawings. However, the appended drawings illustrate only typical embodiments of the disclosure and are therefore not to be considered limiting of scope, for the disclosure may admit to other equally effective embodiments.

FIG. 1 schematically depicts an electron beam apparatus according to embodiments described herein.

FIG. 2A depicts a substrate comprising silicon according to embodiments described herein.

FIG. 2B depicts contacting the substrate shown in FIG. 2A with a fluorine etchant to form a fluorine-containing reaction layer on a surface of the substrate according to embodiments described herein.

FIG. 2C depicts irradiating the fluorine-containing reaction layer on the surface of the substrate shown in FIG. 2B with electrons according to embodiments described herein.

FIG. 2D depicts electron-impact dissociation of the fluorine-containing reaction layer thereby releasing atomic fluorine to etch the surface of the substrate according to embodiments described herein.

FIG. 2E depicts the etched substrate according to embodiments described herein.

FIG. 3 depicts a diagram of the gas flow rates and the application of electrical power of a method of processing a substrate according to embodiments described herein.

FIG. 4 depicts a flow diagram of a method of processing a substrate according to embodiments described herein.

FIG. 5 depicts a depicts an integrated tool in accordance with embodiments disclosed herein.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

In embodiments, a method of processing a substrate consists of, consists essentially of, or comprises contacting the substrate comprising silicon in a processing chamber with a fluorine etchant at a substrate temperature, pressure, and for a period of time sufficient to form a fluorine-containing reaction layer on a surface of the substrate; and irradiating the fluorine-containing reaction layer on the surface of the substrate with electrons having an energy sufficient for electron-impact dissociation of the fluorine-containing reaction layer, thereby releasing atomic fluorine to etch the surface of the substrate. In embodiments, the electrons irradiating the fluorine-containing reaction layer on the surface of the substrate have an average energy from about 50 eV to 20,000 eV. In embodiments, the substrate is contacted with the fluorine etchant at a substrate temperature of less than or equal to about 0° C. In embodiments, the irradiating of the fluorine-containing reaction layer on the surface of the substrate with electrons having an energy sufficient for electron-impact dissociation of the fluorine-containing reaction layer thereby releasing the atomic fluorine to etch the surface of the substrate is conducted at a substrate temperature of less than or equal to about 0° C. In embodiments, a first portion of the substrate is silicon, and a second portion of the substrate comprises silicon oxide and/or silicon nitride, and wherein the first portion is selectively etched relative to the second portion. In embodiments, the substrate is contacted with the fluorine etchant to form the fluorine-containing reaction layer on the surface of the substrate at a pressure from about 5 millitorr to 100 millitorr for about 30 seconds to 5 minutes.

In embodiments, the fluorine etchant comprises HF, FX, FX₂, PFX_{2.}, XeFX, or a combination thereof, wherein each X is independently a halogen. In embodiments, the fluorine etchant consists of, or consists essentially of HF.

In embodiments, the fluorine etchant is present within a mixture comprising an inert gas, which in embodiments is helium, neon, argon, krypton, xenon, or a combination thereof. In embodiments, the method according to one or more embodiments disclosed herein further comprises purging the processing chamber with an inert gas after contacting the substrate with the fluorine etchant to form a fluorine-containing reaction layer on a surface of the substrate, prior to the irradiating the fluorine-containing reaction layer on the surface of the substrate with electrons having an energy sufficient for electron-impact dissociation of the fluorine etchant present in the fluorine-containing reaction layer, thereby releasing atomic fluorine to etch the surface of the substrate. In embodiments, the method according to one or more embodiments disclosed herein further comprises purging the processing chamber with an inert gas after the irradiating the fluorine-containing reaction layer on the surface of the substrate with electrons having an energy sufficient for electron-impact dissociation of the fluorine-containing reaction layer thereby releasing atomic fluorine to etch the surface of the substrate.

In embodiments, the electrons are produced by an electron source separated from the surface of the substrate by a distance from about 1 cm to 50 cm.

In embodiments, a method of etching a substrate comprises an etching cycle comprising: contacting the substrate comprising silicon in a processing chamber with a fluorine etchant at a substrate temperature, pressure, and for a period of time sufficient to form a fluorine-containing reaction layer on a surface of the substrate; purging the processing chamber with an inert gas; irradiating the fluorine-containing reaction layer on the surface of the substrate with electrons having an energy sufficient for electron-impact dissociation of the fluorine-containing reaction layer thereby releasing atomic fluorine to etch the surface of the substrate; and purging the processing chamber with the inert gas. In embodiments, the etching cycle is repeated a plurality of times. In embodiments of the etching cycle, the electrons have an energy from about 50 eV to 20,000 eV, and/or the substrate is contacted with the fluorine etchant at a substrate temperature of less than or equal to about 0° C., and/or the irradiating the fluorine-containing reaction layer on the surface of the substrate with electrons having an energy sufficient for electron-impact dissociation thereby releasing atomic fluorine to etch the surface of the substrate is conducted at a substrate temperature of less than or equal to about 0° C., and/or the substrate is contacted with the fluorine etchant to form the fluorine-containing reaction layer on the surface of the substrate at a pressure from about 5 millitorr to 100 millitorr for about 30 seconds to 5 minutes. In embodiments of the etching cycle, the fluorine etchant comprises HF, FX, FX₂, PFX_{2.}, XeFX, or a combination thereof, wherein each X is independently a halogen, or the fluorine etchant consists essentially of HF.

In embodiments, a non-transitory, computer readable medium having instructions stored thereon that, when executed, cause a method of processing a substrate according to one or more embodiments disclosed herein.

In embodiments, the method includes the physisorption of the fluorine etchant on a surface of the silicon substrate. The fluorine etchant includes fluorine, but may include other materials. In embodiments, suitable fluorine etchants include any material comprising fluorine, which when subject to electron-impact dissociation releases materials capable of anisotropic etching of silicon. In embodiments, the fluorine etchant comprises HF, FX, FX₂, PFX₂, XeFX, or a combination thereof, wherein each X is independently a halogen, e.g., F, Cl, Br, I. In embodiments, the fluorine etchant comprises HF, or consists essentially of HF, or consists of HF.

In embodiments, the substrate is contacted with the fluorine etchant at a substrate temperature of less than or equal to about 0° C., which in embodiments is from greater than or equal to about −90° C. to less than or equal to about 0° C. In embodiments, the substrate is contacted with the fluorine etchant at a substrate temperature from greater than or equal to about −90° C. to less than or equal to about 0° C., or greater than or equal to about −70° C., or greater than or equal to about −50° C., or greater than or equal to about −30° C., or greater than or equal to about −20° C., or greater than or equal to about −10° C., and less than or equal to about 0° C.

In embodiments, the substrate is contacted with the fluorine etchant to form the fluorine-containing reaction layer on the surface of the substrate at a pressure from about 5 millitorr to 100 millitorr. In embodiments, the substrate is contacted with the fluorine etchant to form the fluorine-containing reaction layer on the surface of the substrate at a pressure of greater than or equal to about 5 millitorr, or greater than or equal to about 10 millitorr, or greater than or equal to about 20 millitorr, or greater than or equal to about 30 millitorr, and less than or equal to about 100 millitorr, or less than or equal to about 70 millitorr, or less than or equal to about 50 millitorr, for about 30 seconds to 5 minutes.

The physisorption of the fluorine etchant builds a layer of fluorine-containing molecules on the surface of the substrate. The fluorine-containing reaction layer disposed on the surface of the substrate is then irradiated with electrons from an electron source having an energy sufficient for electron-impact dissociation of the fluorine etchant to etch the surface of the substrate. The fluorine etchant then undergoes electron-impact dissociation to release mono-atomic components of the fluorine etchant, which then etch the silicon. Taking a fluorine etchant of HF as an example, electron-impact dissociation of HF forms atomic hydrogen and fluorine on the surface thereby resulting in the anisotropic etch of the silicon substrate.

In embodiments, the irradiating of the fluorine-containing reaction layer on the surface of the substrate with electrons having an energy sufficient for electron-impact dissociation of the fluorine etchant to etch the surface of the substrate is conducted at a substrate temperature of less than or equal to about 0° C. In embodiments, the irradiating of the fluorine-containing reaction layer on the surface of the substrate with electrons having an energy sufficient for electron-impact dissociation of the fluorine etchant to etch the surface of the substrate is conducted at a substrate temperature of greater than or equal to about −90° C., or greater than or equal to about −70° C., or greater than or equal to about −50° C., or greater than or equal to about −30° C., or greater than or equal to about −20° C., or greater than or equal to about −10° C., and less than or equal to about 10° C., or less than or equal to about 0° C.

In embodiments, the irradiating of the fluorine-containing reaction layer on the surface of the substrate with electrons having an energy sufficient for electron-impact dissociation of the fluorine etchant to etch the surface of the substrate is conducted a pressure from about 5 millitorr to 100 millitorr. In embodiments, the irradiating of the fluorine-containing reaction layer on the surface of the substrate with electrons having an energy sufficient for electron-impact dissociation of the fluorine etchant to etch the surface of the substrate is conducted at a pressure of greater than or equal to about 5 millitorr, or greater than or equal to about 10 millitorr, or greater than or equal to about 20 millitorr, or greater than or equal to about 30 millitorr, and less than or equal to about 100 millitorr, or less than or equal to about 70 millitorr, or less than or equal to about 50 millitorr, for about 30 seconds to 5 minutes.

In embodiments, the processing chamber may be purged with an inert gas after contacting the substrate with the fluorine etchant, prior to the irradiating the fluorine-containing reaction layer on the surface of the substrate with electrons. In embodiments, the processing chamber may be purged with an inert gas after the irradiating the fluorine-containing reaction layer on the surface of the substrate with electrons having an energy sufficient for electron-impact dissociation of the fluorine etchant to etch the surface of the substrate.

In embodiments, the method of processing a substrate according to embodiments disclosed herein is conducted in a processing chamber configured to produce an electron beam in which the electrons have an energy sufficient for electron-impact dissociation of the fluorine etchant to etch the surface of the substrate. In embodiments, the electrons have an average energy from about 50 eV to 20,000 eV.

In embodiments, the electrons utilized to irradiate the fluorine-containing reaction layer on the surface of the substrate are produced by an electron source capable of generating an electron beam. Suitable examples include DC voltage extraction from an electron source, electron beam reactive plasma etching, and the like.

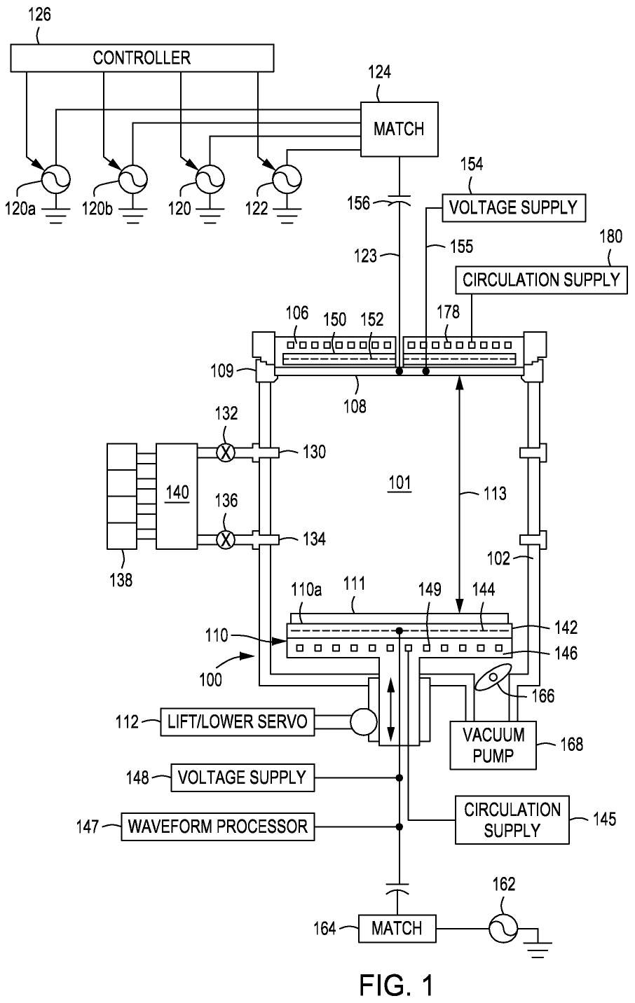

FIG. 1 depicts a processing chamber 100 configured to produce an electron beam. The processing chamber 100 has a chamber body 102 which defines a process volume 101. In one embodiment, the chamber body 102 has a substantially cylindrical shape. In other embodiments, the chamber body 102 has a polygonal shape, such as a cubic shape or the like. The chamber body 102 is fabricated from a material suitable for maintaining a vacuum pressure environment therein, such as metallic materials, for example aluminum or stainless steel.

A ceiling 106 is coupled to the chamber body 102 and further defines the process volume 101. In one embodiment, the ceiling 106 is formed from an electrically conductive material, such as the materials utilized to fabricate the chamber body 102. The ceiling 106 is coupled to and supports an electrode 108 thereon. In one embodiment, the electrode 108 is coupled to the ceiling 106 such that the electrode 108 is disposed adjacent the process volume 101. In one embodiment, the electrode 108 is formed from a process-compatible material having a high secondary electron emission coefficient, such as silicon, carbon, silicon carbon materials, or silicon-oxide materials. Alternatively, the electrode 108 is formed from a metal oxide material such as aluminum oxide, yttrium oxide, or zirconium oxide. A dielectric ring 109, which is formed from an electrically insulating material, is coupled to the chamber body 102 and surrounds the electrode 108. As illustrated, the dielectric ring 109 is disposed between the chamber body 102 and the ceiling 106 and supports the electrode 108 thereon.

A pedestal 110 is disposed in the process volume 101. The pedestal 110 supports a substrate 111 thereon and has a substrate support surface 110a oriented parallel to the electrode 108. In one embodiment, the pedestal 110 is movable in the axial direction by a lift servo 112. During operation, a substrate support surface 110a is maintained at a separation distance 113 of between about 1 cm and about 50 cm from the electron source, e.g., the electrode 108. In one embodiment, the pedestal 110 includes an insulating puck 142 which forms the substrate support surface 110a, an electrode 144 disposed inside the insulating puck 142, and a chucking voltage supply 148 connected to the electrode 144. Additionally, a base layer 146 underlying the insulating puck 142 has internal passages 149 for circulating a thermal transfer medium (e.g., a liquid) from a circulation supply 145. In one embodiment, the circulation supply 145 functions as a heat sink. In another embodiment, the circulation supply 145 functions as a heat source. In one embodiment, a temperature of the pedestal 110 is maintained between about −90° C. and about 0° C.

In embodiments, an RF power generator 120 having a VHF frequency and a lower frequency RF power generator 122 having a frequency below the VHF range or below the HF range may be coupled to the electrode 108 through an impedance match 124 via an RF feed conductor 123.

In embodiments, the RF power generator 120 is replaced by two VHF power generators 120a and 120b that are separately controlled. The controller 126 governs plasma ion density by selecting the ratio between the output power levels of the VHF power generators 120a and 120b.

In embodiments, the ceiling 106 is a support for the electrode 108 and includes an insulating layer 150 containing a chucking electrode 152 facing the electrode 108. A D.C. chucking voltage supply 154 is coupled to the chucking electrode 152 via the feed conductor 155, for electrostatically clamping the electrode 108 to the ceiling 106. A D.C. blocking capacitor 156 is connected in series with the output of the impedance match 124. The controller 126 functions to control the D.C. chucking voltage supply 154. In one embodiment, the RF feed conductor 123 from the impedance match 124 is connected to the electrode support or ceiling 106 rather than being directly connected to the electrode 108. In such an embodiment, RF power from the RF feed conductor 123 is capacitively coupled from the electrode support to the electrode 108.

In embodiments, internal passages 178 for conducting a thermally conductive liquid or media inside the ceiling 106 are connected to a thermal media circulation supply 180. The thermal media circulation supply 180 acts as a heat sink or a heat source. The mechanical contact between the electrode 108 and the ceiling 106 is sufficient to maintain high thermal conductance between the electrode 108 and the ceiling 106. In the embodiment of FIG. 1, the force of the mechanical contact is regulated by the electrostatic clamping force provided by the D.C. chucking voltage supply 154.

In embodiments, upper gas injectors 130 provide process gas into the process volume 101 through a first valve 132. In one embodiment, lower gas injectors 134 provide process gas into the process volume 101 through a second valve 136. The upper gas injectors 130 and the lower gas injectors 134 are disposed in sidewalls of the chamber body 102. Gas, e.g., the fluorine etchant, and/or an inert carrier or processing gas, is supplied from an array of gas supplies 138 through an array of valves 140 which may include the first valve 132 and the second valve 136, respectively. In one embodiment, gas species and gas flow rates delivered into the process volume 101 are independently controllable. For example, gas flow through the upper gas injectors 130 may be different from gas flow through the lower gas injectors 134. The controller 126 governs the array of valves 140.

In embodiments, a plasma is generated in the process volume 101 by various bulk and surface processes, for example, by capacitive coupling. In one embodiment, plasma generation is also facilitated by energetic ion bombardment of the interior surface of the electrode 108, e.g., the electron-emitting electrode. In one example, the electrode 108 is biased with a substantially negative charge, such as by application of voltage form the chucking voltage supply 154. In one embodiment, bias power applied to the electrode 108 is between about 1 KW and about 10 KW with a frequency of between about 400 KHz and about 200 MHz. The inventors believe that ions generated by a capacitively coupled plasma are influenced by an electric field that encourages bombardment of the electrode 108 by the ions generated from the plasma.

The ion bombardment energy of the electrode 108 and the plasma density are functions of both RF power generators 120 and 122. The ion bombardment energy of the electrode 108 is substantially controlled by the lower frequency power from the lower frequency RF power generator 122 and the plasma density in the process volume 101 is substantially controlled (enhanced) by the VHF power from the RF power generator 120. The inventors believe that ion bombardment of the electrode 108 causes the electrode to emit secondary electrons. Energetic secondary electrons, which have a negative charge, are emitted from the interior surface of the electrode 108 and accelerated away from the electrode due to the negative bias of the electrode 108.

In embodiments, an RF bias power generator 162 is coupled through an impedance match 164 to the electrode 144 of the pedestal 110. In a further embodiment, a waveform tailoring processor 147 may be connected between the output of the impedance match 164 and the electrode 144. The waveform tailoring processor 147 changes the waveform produced by the RF bias power generator 162 to a desired waveform. The ion energy of plasma near the substrate 111 is controlled by the waveform tailoring processor 147. In one embodiment, the waveform tailoring processor 147 produces a waveform in which the amplitude is held during a certain portion of each RF cycle at a level corresponding to a desired ion energy level. The controller 126 controls the waveform tailoring processor 147.

The flux of energetic electrons from the emitting surface of the electrode 108 is believed to be an electron beam, and may be oriented substantially perpendicular to the interior surface of the electrode 108. A beam energy of the electron beam i.e., the electrons, is approximately equal to the ion bombardment energy of the electrode 108, which typically can range from about 50 eV to 20,000 eV. In embodiments, the electrons have an energy of greater than or equal to about 100 eV, or greater than or equal to about 250 eV, or greater than or equal to about 500 eV, or greater than or equal to about 700 eV, or greater than or equal to about 1,000 eV, or greater than or equal to about 5,000 eV, and less than or equal to about 20,000 eV, or less than or equal to about 15,000 eV, or less than or equal to about 10,000 eV.

In embodiments, the plasma potential is greater than the potential of the electrode 108 and the energetic secondary electrons emitted from the electrode 108 are further accelerated by a sheath voltage of the plasma as the secondary electrons traverse through the plasma.

In embodiments at least a portion of the electron beam, comprised of the secondary electron flux emitted from electrode 108 due to energetic ion bombardment of the electrode surface, propagates through the process volume 101 irradiating the fluorine-containing reaction layer on the surface of the substrate with electrons having an energy sufficient for electron-impact dissociation of the fluorine etchant to etch the surface of the substrate.

The inventors believe that the electron beams, in addition to the capacitively generated plasma, generate chemically reactive radicals and ions which adsorb to the surface of the substrate and form a chemically reactive layer of the surface of the substrate 111. The electron beam bombardment of the chemically reactive layer causes generation of volatile products which results in etching (material removal) of the substrate 111. Accordingly, in embodiments in which the substrate comprises a first portion of silicon, and a second portion of the substrate comprises silicon oxide and/or silicon nitride, the first portion is selectively etched relative to the second portion. In embodiments, the selectivity of the etching is greater than or equal to about 2:1 silicon to other material, or greater than or equal to about 5:1 silicon to other material, or greater than or equal to about 10:1 silicon to other material due to the formation of volatile products from the fluorine etchant and the silicon substrate.

In addition, the inventors have discovered that the methods disclosed herein greater increase and/or eliminate byproduct redeposition relative chemisorption of chlorine followed by ion irradiation. Furthermore, the inventors have discovered that, unlike chemisorption, physisorption is not limited to a few monolayers. Since the methods disclosed herein proceed with physisorption of the fluorine etchant molecules followed by electron-irradiation, the etch rate of methods disclosed herein is significantly higher than the chemisorption chlorine-based cyclic etch of silicon.

In addition, chlorine-based cyclic etch of silicon requires a very tight control of ion energy to achieve selectivity toward silicon oxide and silicon nitride. In contrast, methods according to the instant disclosure do not rely solely on the control of energy of charged species to obtain the higher selectivity of silicon relative to silicon oxide and silicon nitride, which are also controlled via the chemical reactions between the monoatomic fluorine and the silicon substrate which form the volatile products that result in etching.

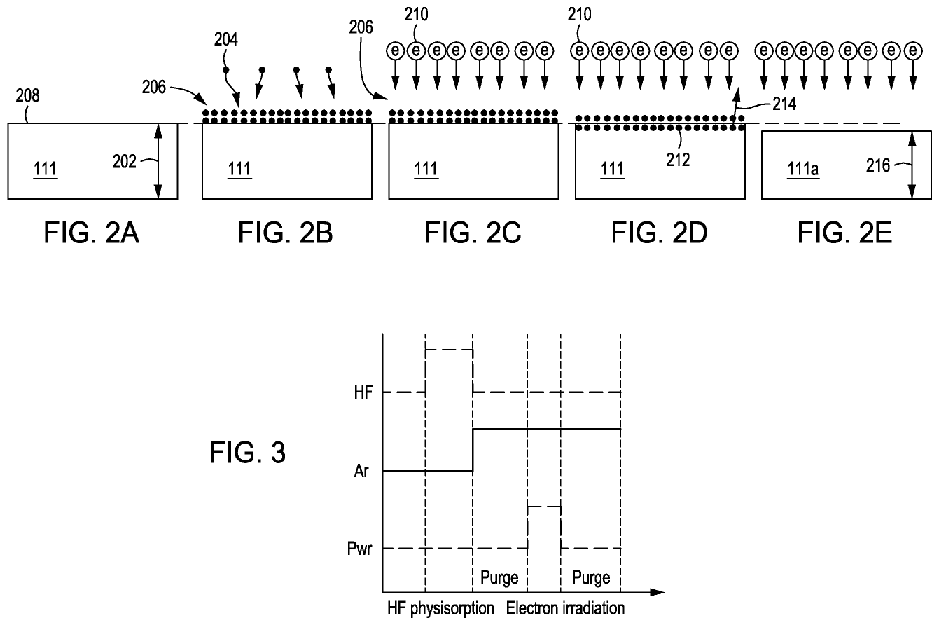

FIGS. 2A-2E depict processing a silicone substrate according to an embodiment disclosed herein. FIG. 2A shows a substrate 111 comprising silicone having an initial thickness 202. FIG. 2B depicts the contacting of the substrate 111 comprising silicon with a fluorine etchant 204 (only one is labeled for clarity) at a substrate temperature, pressure, and for a period of time sufficient to form a fluorine-containing reaction layer 206 of the fluorine etchant 204 on a surface 208 of the substrate 111. FIG. 2C depicts the irradiating of the fluorine etchant 204 of the fluorine-containing reaction layer 206 on the surface 208 of the substrate with electrons 210 (only one of which is labeled for clarity) having an energy sufficient for electron-impact dissociation of the fluorine-containing reaction layer 206, thereby releasing atomic fluorine 212 (see FIG. 2D) to etch the surface 208 of the substrate. FIG. 2D depicts the resultant chemically reactive radicals e.g., the atomic fluorine 212 (only one is labeled for clarity) which adsorb to the surface 208 of the substrate 111, reacting with the silicon to form a volatile material 214 (only one is shown for clarity) which evaporates or otherwise separates or is removed from the surface 208 of the substrate 111 to etch the surface 208 of the substrate 111. FIG. 2E depicts the etched substrate 111a, having a final thickness 216 which is less than the initial thickness 202.

FIG. 3 depicts the relative flow rates of the fluorine etchant (HF), an inert gas (Ar), and the application of power to the electrodes of the processing chamber, wherein the chamber is purged after forming a fluorine-containing reaction layer on a surface of the substrate, and after the electron irradiation of the substrate.

Accordingly, the electron beam causes electron-impact dissociation of the fluorine etchant, which induces chemical reactions to liberate gas phase volatile products and etch the substrate 111. Etching of the substrate 111 is also influenced by other factors, such as pressure and substrate temperature.

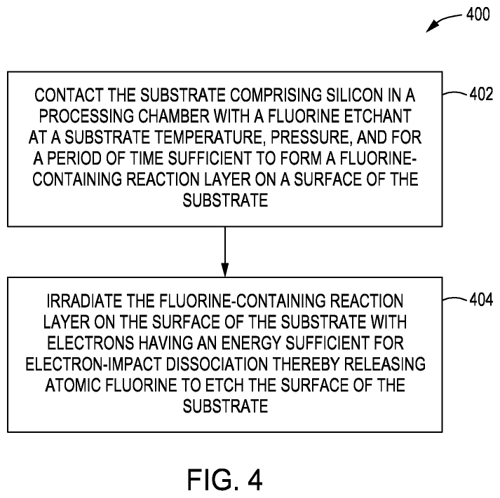

FIG. 4 is a flowchart of a method 400 according to embodiments disclosed herein. In some embodiments, blocks 402 and 404 of FIG. 4 may be performed by a device.

As shown in FIG. 4, method 400 includes contacting the substrate comprising silicon in a processing chamber with a fluorine etchant at a substrate temperature, pressure, and for a period of time sufficient to form a fluorine-containing reaction layer on a surface of the substrate (block 402), followed by irradiating the fluorine-containing reaction layer on the surface of the substrate with electrons having an energy sufficient for electron-impact dissociation of the fluorine etchant to etch the surface of the substrate (block 404).

Although FIG. 4 shows exemplary blocks of method 400, in some implementations, method 400 may include additional blocks.

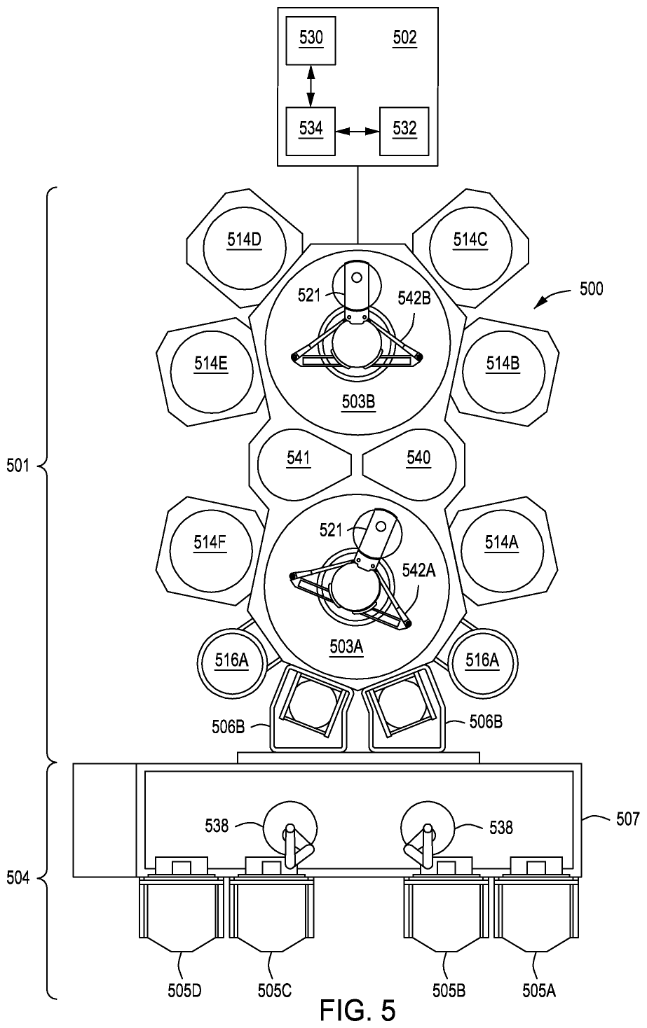

The methods described herein may be performed in individual process chambers that may be provided in a standalone configuration or as part of one or more cluster tools, for example, an integrated tool 500 (i.e., cluster tool) described below with respect to FIG. 5. In some embodiments, the method described herein may be performed in individual process chambers provided as a standalone chamber or as part of a cluster tool. In embodiments, a cluster tool is configured for performing the methods for processing a substrate as described herein.

The methods described herein may be practiced using any cluster tool having suitable process chambers coupled thereto, or in other suitable process chambers. For example, in some embodiments the inventive methods discussed above may advantageously be performed in an integrated tool such that there are limited or no vacuum breaks while processing.

The methods described herein may be performed in individual process chambers that may be provided in a standalone configuration or as part of a cluster tool, for example, the integrated tool 500 (i.e., cluster tool) described below with respect to FIG. 5. The advantage of using an integrated tool 500 is that there is no vacuum break between chambers and, therefore, no requirement to degas and pre-clean a substrate before treatment in a chamber. For example, in some embodiments the methods discussed above may advantageously be performed in an integrated tool such that there are limited or no vacuum breaks between processes, limiting or preventing contamination of the substrate such as oxidation and the like. The integrated tool 500 includes a vacuum-tight processing platform 501, a factory interface 504, and a system controller 502. The processing platform 501 comprises multiple processing chambers, such as 514A, 514B, 514C, 514D, 514E, and 514F operatively coupled to a vacuum substrate transfer chamber (transfer chambers 503A, 503B). The factory interface 504 is operatively coupled to the transfer chamber 503A by one or more load lock chambers (two load lock chambers, such as 506A and 506B shown in FIG. 5).

In some embodiments, the factory interface 504 comprises at least one docking station 507, and at least one factory interface robot 538 to facilitate the transfer of the semiconductor substrates. The docking station 507 is configured to accept one or more front opening unified pods (FOUP). Four FOUPS, such as 505A, 505B, 505C, and 505D are shown in the embodiment of FIG. 5. The factory interface robot 538 is configured to transfer the substrates from the factory interface 504 to the processing platform 501 through the load lock chambers, such as 506A and 506B. Each of the load lock chambers 506A and 506B have a first port coupled to the factory interface 504 and a second port coupled to the transfer chamber 503A. The load lock chamber 506A and 506B are coupled to a pressure control system (not shown) which pumps down and vents the load lock chambers 506A and 506B to facilitate passing the substrates between the vacuum environment of the transfer chamber 503A and the substantially ambient (e.g., atmospheric) environment of the factory interface 504. The transfer chambers 503A, 503B have vacuum robots 542A, 542B disposed in the respective transfer chambers 503A, 503B. The vacuum robot 542A is capable of transferring substrates 521 between the load lock chamber 506A, 506B, the processing chambers 514A and 514F and a cooldown station 540 or a pre-clean station 541. The vacuum robot 542B is capable of transferring substrates 521 between the cooldown station 540 or pre-clean station 541 and the processing chambers 514B, 514C, 514D, and 514E.

In some embodiments, the processing chambers 514A, 514B, 514C, 514D, 514E, and 514F are coupled to the transfer chambers 503A, 503B. In addition to processing chambers suitable for processing a substrate according to embodiments of the methods disclosed herein, the processing chambers 514A, 514B, 514C, 514D, 514E, and 514F may further comprise, for example, atomic layer deposition process chambers, physical vapor deposition process chambers, chemical vapor deposition chambers, annealing chambers, or the like. The chambers may include any chambers suitable to perform all or portions of the methods described herein, as discussed above. In some embodiments, one or more optional service chambers (shown as 516A and 516B) may be coupled to the transfer chamber 503A. The service chambers 516A and 516B may be configured to perform other substrate processes, such as degassing, orientation, substrate metrology, cool down, and the like.

The system controller 502 controls the operation of the tool 500 using a direct control of the process chambers 514A, 514B, 514C, 514D, 514E, and 514F or alternatively, by controlling the computers (or controllers) associated with the process chambers 514A, 514B, 514C, 514D, 514E, and 514F and the tool 500. In operation, the system controller 502 enables data collection and feedback from the respective chambers and systems to optimize performance of the tool 500. The system controller 502 generally includes a central processing unit (CPU) 530, a memory 534, and a support circuit 532. The CPU 530 may be any form of a general-purpose computer processor that can be used in an industrial setting. The support circuit 532 is conventionally coupled to the CPU 530 and may comprise a cache, clock circuits, input/output subsystems, power supplies, and the like. Software routines, such as a method as described above may be stored in the memory 534 and, when executed by the CPU 530, transform the CPU 530 into a specific purpose computer (system controller) 502. The software routines may also be stored and/or executed by a second controller (not shown) that is located remotely from the tool 500.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

### Embodiments

Embodiments of the instant application include, but are not limited to:

E1. A method of processing a substrate, comprising:
contacting the substrate comprising silicon in a processing chamber with a fluorine etchant at a substrate temperature, pressure, and for a period of time sufficient to form a fluorine-containing reaction layer on a surface of the substrate; and
irradiating the fluorine-containing reaction layer on the surface of the substrate with electrons having an energy sufficient for electron-impact dissociation thereby releasing atomic fluorine to etch the surface of the substrate.

E2. The method according to embodiment E1, wherein the electrons have an energy from about 50 eV to 20,000 eV.

E3. The method according to embodiments E1-E2, wherein the substrate is contacted with the fluorine etchant at a substrate temperature less than or equal to about 0° C.

E4. The method according to embodiments E1-E3, wherein the irradiating the fluorine-containing reaction layer on the surface of the substrate with electrons having an energy sufficient for electron-impact dissociation of the fluorine etchant to etch the surface of the substrate is conducted at a substrate temperature of less than or equal to about 0° C.

E5. The method according to embodiments E1-E4, wherein a first portion of the substrate is silicon, and a second portion of the substrate comprises silicon oxide and/or silicon nitride, and wherein the first portion is selectively etched relative to the second portion.

E6. The method according to embodiments E1-E5, wherein the substrate is contacted with the fluorine etchant to form the fluorine-containing reaction layer on the surface of the substrate at a pressure from about 5 millitorr to 100 millitorr for about 30 seconds to 5 minutes.

E7. The method according to embodiments E1-E6, wherein the fluorine etchant comprises HF, FX, FX₂, PFX_{2.}, XeFX, or a combination thereof, wherein each X is independently a halogen.

E8. The method according to embodiments E1-E7, wherein the fluorine etchant consists essentially of HF.

E9. The method according to embodiments E1-E8, wherein the fluorine etchant is present within a mixture comprising helium, neon, argon, krypton, xenon, or a combination thereof.

E10. The method according to embodiments E1-E9, further comprising purging the processing chamber with an inert gas after contacting the substrate with the fluorine etchant, prior to the irradiating the fluorine-containing reaction layer on the surface of the substrate with electrons having an energy sufficient for electron-impact dissociation thereby releasing atomic fluorine to etch the surface of the substrate.

E11. The method according to embodiments E1-E10, further comprising purging the processing chamber with an inert gas after the irradiating the fluorine-containing reaction layer on the surface of the substrate with electrons having an energy sufficient for electron-impact dissociation thereby releasing atomic fluorine to etch the surface of the substrate.

E12. The method according to embodiments E1-E11, wherein the electrons are produced by an electron source separated from the surface of the substrate by a distance from about 1 cm to 50 cm.

E13. A method of etching a substrate comprising an etching cycle comprising:
contacting the substrate comprising silicon in a processing chamber with a fluorine etchant at a substrate temperature, pressure, and for a period of time sufficient to form a fluorine-containing reaction layer on a surface of the substrate;
purging the processing chamber with an inert gas;
irradiating the fluorine-containing reaction layer on the surface of the substrate with electrons having an energy sufficient for electron-impact dissociation of the fluorine etchant to etch the surface of the substrate; and
purging the processing chamber with the inert gas,
wherein the etching cycle is repeated a plurality of times.

E14. The method according to embodiment E13, wherein the electrons have an energy from about 50 eV to 20,000 eV.

E15. The method according to embodiments E13-E14, wherein the substrate is contacted with the fluorine etchant at a substrate temperature of less than or equal to about 0° C.;
wherein the irradiating the fluorine-containing reaction layer on the surface of the substrate with electrons having an energy sufficient for electron-impact dissociation of the fluorine etchant to etch the surface of the substrate is conducted at a substrate temperature of less than or equal to about 0° C.;
or a combination thereof.

E16. The method according to embodiments E13-E15, wherein the substrate is contacted with the fluorine etchant to form the fluorine-containing reaction layer on the surface of the substrate at a pressure from about 5 millitorr to 100 millitorr for about 30 seconds to 5 minutes.

E17. The method according to embodiments E13-E16, wherein the fluorine etchant comprises HF, FX, FX₂, PFX_{2.}, XeFX, or a combination thereof, wherein each X is independently a halogen.

E18. The method according to embodiments E13-E17, wherein the fluorine etchant consists essentially of HF.

E19. A non-transitory, computer readable medium having instructions stored thereon that, when executed, cause a method of processing a substrate according to embodiments E1-E18.

E20. A non-transitory, computer readable medium having instructions stored thereon that, when executed, cause a method of processing a substrate comprising a processing cycle, comprising:
contacting the substrate comprising silicon in a processing chamber with a fluorine etchant at a substrate temperature, pressure, and for a period of time sufficient to form a fluorine-containing reaction layer on a surface of the substrate; and
irradiating the fluorine-containing reaction layer on the surface of the substrate with electrons having an energy sufficient for electron-impact dissociation thereby releasing atomic fluorine to etch the surface of the substrate.

E21. The non-transitory, computer readable medium according to embodiments E19-E20, wherein the processing cycle further includes purging the processing chamber with an inert gas after contacting the substrate with the fluorine etchant, prior to the irradiating the fluorine-containing reaction layer on the surface of the substrate with electrons having an energy sufficient for electron-impact dissociation of the fluorine etchant to etch the surface of the substrate; and/or purging the processing chamber with an inert gas after the irradiating the fluorine-containing reaction layer on the surface of the substrate with electrons having an energy sufficient for electron-impact dissociation of the fluorine etchant to etch the surface of the substrate.

While the foregoing is directed to embodiments of the present disclosure, other and further embodiments of the disclosure may be devised without departing from the basic scope thereof.

1. A method of processing a substrate, comprising:
contacting the substrate comprising silicon in a processing chamber with a fluorine etchant at a substrate temperature, pressure, and for a period of time sufficient to form a fluorine-containing reaction layer on a surface of the substrate; and
irradiating the fluorine-containing reaction layer on the surface of the substrate with electrons having an energy sufficient for electron-impact dissociation thereby releasing atomic fluorine to etch the surface of the substrate.

2. The method of claim 1, wherein the electrons have an energy from about 50 eV to 20,000 eV.

3. The method of claim 1, wherein the substrate is contacted with the fluorine etchant at a substrate temperature less than or equal to about 0° C.

4. The method of claim 1, wherein the irradiating the fluorine-containing reaction layer on the surface of the substrate with electrons having an energy sufficient for electron-impact dissociation of the fluorine etchant to etch the surface of the substrate is conducted at a substrate temperature of less than or equal to about 0° C.

5. The method of claim 1, wherein a first portion of the substrate is silicon, and a second portion of the substrate comprises silicon oxide and/or silicon nitride, and wherein the first portion is selectively etched relative to the second portion.

6. The method of claim 1, wherein the substrate is contacted with the fluorine etchant to form the fluorine-containing reaction layer on the surface of the substrate at a pressure from about 5 millitorr to 100 millitorr for about 30 seconds to 5 minutes.

7. The method of claim 1, wherein the fluorine etchant comprises HF, FX, FX₂, PFX_{2.}, XeFX, or a combination thereof, wherein each X is independently a halogen.

8. The method of claim 1, wherein the fluorine etchant consists essentially of HF.

9. The method of claim 1, wherein the fluorine etchant is present within a mixture comprising helium, neon, argon, krypton, xenon, or a combination thereof.

10. The method of claim 1, further comprising purging the processing chamber with an inert gas after contacting the substrate with the fluorine etchant, prior to the irradiating the fluorine-containing reaction layer on the surface of the substrate with electrons having an energy sufficient for electron-impact dissociation thereby releasing atomic fluorine to etch the surface of the substrate.

11. The method of claim 1, further comprising purging the processing chamber with an inert gas after the irradiating the fluorine-containing reaction layer on the surface of the substrate with electrons having an energy sufficient for electron-impact dissociation thereby releasing atomic fluorine to etch the surface of the substrate.

12. The method of claim 1, wherein the electrons are produced by an electron source separated from the surface of the substrate by a distance from about 1 cm to 50 cm.

13. A method of etching a substrate comprising an etching cycle comprising:
contacting the substrate comprising silicon in a processing chamber with a fluorine etchant at a substrate temperature, pressure, and for a period of time sufficient to form a fluorine-containing reaction layer on a surface of the substrate;
purging the processing chamber with an inert gas;
irradiating the fluorine-containing reaction layer on the surface of the substrate with electrons having an energy sufficient for electron-impact dissociation of the fluorine etchant to etch the surface of the substrate; and
purging the processing chamber with the inert gas,
wherein the etching cycle is repeated a plurality of times.

14. The method of claim 13, wherein the electrons have an energy from about 50 eV to 20,000 eV.

15. The method of claim 13, wherein the substrate is contacted with the fluorine etchant at a substrate temperature of less than or equal to about 0° C.;
wherein the irradiating the fluorine-containing reaction layer on the surface of the substrate with electrons having an energy sufficient for electron-impact dissociation of the fluorine etchant to etch the surface of the substrate is conducted at a substrate temperature of less than or equal to about 0° C.;
or a combination thereof.

16. The method of claim 13, wherein the substrate is contacted with the fluorine etchant to form the fluorine-containing reaction layer on the surface of the substrate at a pressure from about 5 millitorr to 100 millitorr for about 30 seconds to 5 minutes.

17. The method of claim 13, wherein the fluorine etchant comprises HF, FX, FX₂, PFX_{2.}, XeFX, or a combination thereof, wherein each X is independently a halogen.

18. The method of claim 13, wherein the fluorine etchant consists essentially of HF.

19. A non-transitory, computer readable medium having instructions stored thereon that, when executed, cause a method of processing a substrate comprising a processing cycle, comprising:
contacting the substrate comprising silicon in a processing chamber with a fluorine etchant at a substrate temperature, pressure, and for a period of time sufficient to form a fluorine-containing reaction layer on a surface of the substrate; and
irradiating the fluorine-containing reaction layer on the surface of the substrate with electrons having an energy sufficient for electron-impact dissociation thereby releasing atomic fluorine to etch the surface of the substrate.

20. The non-transitory, computer readable medium of claim 19,
wherein the processing cycle further includes purging the processing chamber with an inert gas after contacting the substrate with the fluorine etchant, prior to the irradiating the fluorine-containing reaction layer on the surface of the substrate with electrons having an energy sufficient for electron-impact dissociation of the fluorine etchant to etch the surface of the substrate; and/or
purging the processing chamber with an inert gas after the irradiating the fluorine-containing reaction layer on the surface of the substrate with electrons having an energy sufficient for electron-impact dissociation of the fluorine etchant to etch the surface of the substrate.
